(19) United States
(12) Patent Application Publication
(10) Pub. No.: US 2022/0310803 A1
(43) Pub. Date: Sep. 29, 2022

(54) SEMICONDUCTOR DEVICE AND METHOD OF MANUFACTURING SEMICONDUCTOR DEVICE

(71) Applicant: SUMITOMO ELECTRIC DEVICE INNOVATIONS, INC., Kanagawa (JP)

(72) Inventors: Tadashi WATANABE, Kanagawa (JP); Yukinori NOSE, Kanagawa (JP)

(21) Appl. No.: 17/653,719

(22) Filed: Mar. 7, 2022

(30) Foreign Application Priority Data
Mar. 29, 2021 (JP) 2021-055491

(51) Int. Cl. H01L 29/40; H01L 29/20; H01L 29/778; H01L 21/02; H01L 21/76; H01L 21/765; H01L 29/66

(52) U.S. Cl. CPC H01L 29/408; H01L 29/2003; H01L 29/402; H01L 29/7786; H01L 21/0217; H01L 21/02178; H01L 21/7605; H01L 21/765; H01L 29/66462

(57) ABSTRACT

A semiconductor device includes a substrate, a nitride semiconductor layer formed on the substrate, a source electrode and a drain electrode formed in the nitride semiconductor layer. The source electrode and drain electrode are arranged side by side in a first direction. A gate electrode is formed on the nitride semiconductor layer between the source electrode and the drain electrode. A first protective film is formed on the nitride semiconductor layer, and covers the first protective film covering the source electrode, the drain electrode, and the gate electrode. A source field plate is formed on the first protective film between the gate electrode and the drain electrode in a plan view. A dielectric-breakdown inhibition portion includes a part positioned between an end of the source field plate and an end of the drain electrode in a sectional view, and inhibits dielectric breakdown of the first protective film.

### CROSS REFERENCE TO RELATED APPLICATIONS

This application claims priority to Japanese Patent Application No. 2021-055491 filed on Mar. 29, 2021, and the entire contents of the Japanese patent application are incorporated herein by reference.

### TECHNICAL FIELD

The present disclosure relates to a semiconductor device and a method of manufacturing a semiconductor device.

### BACKGROUND ART

Conventionally, a semiconductor device including a source field plate connected to a source electrode has been proposed (see Patent Document 1).
[Patent Document 1] Japanese Unexamined Patent Application Publication No. 2019-516244
[Patent Document 2] Japanese Unexamined Patent Application Publication No. 2019-169552
[Patent Document 3] Japanese Unexamined Patent Application Publication No. 2019-537284

### SUMMARY OF THE INVENTION

A semiconductor device according to the present disclosure includes a substrate, a nitride semiconductor layer formed on the substrate, a source electrode and a drain electrode formed in the nitride semiconductor layer, the source electrode and the drain electrode being arranged side by side in a first direction parallel to a first main surface of the substrate, a gate electrode formed on the nitride semiconductor layer, the gate electrode being positioned between the source electrode and the drain electrode, a first protective film formed on the nitride semiconductor layer, the first protective film covering the source electrode, the drain electrode, and the gate electrode, a source field plate formed on the first protective film, the source field plate being electrically connected to the source electrode, the source field plate being positioned between the gate electrode and the drain electrode in a plan view in a direction perpendicular to the first main surface and a dielectric-breakdown inhibition portion including a part positioned between an end of the source field plate on the drain electrode side and an end of the drain electrode on the source field plate side in a sectional view in a second direction parallel to the first main surface and perpendicular to the first direction, and that is the dielectric-breakdown inhibition portion being configured to inhibit dielectric breakdown of the first protective film.

### BRIEF DESCRIPTION OF THE DRAWINGS

FIG. 1 is a cross-sectional view illustrating a semiconductor device according to a first embodiment;

FIG. 2 is a first cross-sectional view illustrating an effect of the semiconductor device according to the first embodiment;

FIG. 3 is a second cross-sectional view illustrating the effect of the semiconductor device according to the first embodiment;

FIG. 4 is a first cross-sectional view illustrating a method for manufacturing the semiconductor device according to the first embodiment;

FIG. 5 is a second cross-sectional view illustrating the method for manufacturing the semiconductor device according to the first embodiment;

FIG. 6 is a third cross-sectional view illustrating the method for manufacturing the semiconductor device according to the first embodiment;

FIG. 7 is a fourth cross-sectional view illustrating the method for manufacturing the semiconductor device according to the first embodiment;

FIG. 8 is a fifth cross-sectional view illustrating the method for manufacturing the semiconductor device according to the first embodiment;

FIG. 9 is a sixth cross-sectional view illustrating the method for manufacturing the semiconductor device according to the first embodiment;

FIG. 10 is a seventh cross-sectional view illustrating the method for manufacturing the semiconductor device according to the first embodiment;

FIG. 11 is a first cross-sectional view illustrating a method of forming an insulating film and a space;

FIG. 12 is a second cross-sectional view illustrating the method of forming the insulating film and the space;

FIG. 13 is a third cross-sectional view illustrating the method of forming the insulating film and the space;

FIG. 14 is a fourth cross-sectional view illustrating the method of forming the insulating film and the space;

FIG. 15 is a cross-sectional view illustrating a semiconductor device according to a second embodiment;

FIG. 16 is a first cross-sectional view illustrating a method for forming an insulating film and a second protective film;

FIG. 17 is a second cross-sectional view illustrating the method of forming the insulating film and the second protective film;

FIG. 18 is a cross-sectional view illustrating a semiconductor device according to a third embodiment; and

FIG. 19 is a diagram illustrating an I-V characteristic.

### DETAILED DESCRIPTION OF THE DISCLOSURE

In a conventional semiconductor device including a source field plate, if the distance between a gate electrode and a drain electrode is shortened, a dielectric breakdown may occur in a protective film between the source field plate and the drain electrode.

An object of the present disclosure is to provide a semiconductor device capable of inhibiting a dielectric breakdown of a protective film between a source field plate and a drain electrode, and a method of manufacturing semiconductor device.

Embodiments of the present disclosure will be described below.

[Description of Embodiments of the Present Disclosure]

First, embodiments of the present disclosure will be listed and described.

[1] A semiconductor device according to one aspect of the present disclosure includes a substrate, a nitride semiconductor layer formed on the substrate, a source electrode and a drain electrode formed in the nitride semiconductor layer, the source electrode and the drain electrode being arranged side by side in a first direction parallel to a first main surface of the substrate, a gate electrode formed on the nitride semiconductor layer, the gate electrode being positioned between the source electrode and the drain electrode, a first protective film formed on the nitride semiconductor layer, the first protective film covering the source electrode, the drain electrode, and the gate electrode, a source field plate formed on the first protective film, the source filed plate being electrically connected to the source electrode, the source filed plate being positioned between the gate electrode and the drain electrode in a plan view in a direction perpendicular to the first main surface and a di electric-breakdown inhibition portion including a part positioned between an end of the source field plate on the drain electrode side and an end of the drain electrode on the source field plate side in a sectional view in a second direction parallel to the first main surface and perpendicular to the first direction, and that is the dielectric-breakdown inhibition portion being configured to inhibit dielectric breakdown of the first protective film.

When the semiconductor device operates, an electric field is generated between the source field plate and the drain electrode, and a plurality of defects occur in the first protective film over operating time. As the operating time is longer, defects are connected to each other. However, because the dielectric-breakdown inhibition portion is provided, continuity of defects between the source field plate and the drain electrode is prevented. Therefore, a generation of a leak path connecting the source field plate and the drain electrode is inhibited, and dielectric breakdown of the first protective film is inhibited.

[2] In [1], the dielectric-breakdown inhibition portion may include a space formed in the first protective film. In this case, since defect that becomes a leak path does not occur in the space, dielectric breakdown can be more easily inhibited.

[3] In [1], the dielectric-breakdown inhibition portion may include a second protective film that has a film density higher than a film density of the first protective film. In this case, since defects are less likely to occur in the second protective film than in the first protective film, dielectric breakdown can be suppressed.

[4] In [3], the first protective film may be a Si nitride film, and the second protective film may be an Al oxide film. In this case, it is easy to form the Si nitride film and the Al oxide film using an existing manufacturing apparatus.

[5] In [3] or [4], the second protective film may be embedded in the first protective film. In this case, the second protective film can be easily disposed between the source field plate and the drain electrode.

[6] In [1] to [5], the dielectric-breakdown inhibition portion may include a part that is positioned on, among line segments that connect a point in the source field plate and a point in the drain electrode, a shortest line segment in the sectional view. In this case, because the dielectric-breakdown inhibition portion is located on line segment where a leak path is likely to occur, dielectric breakdown is likely to be inhibited.

[7] In [1] to [6], in the sectional view, the drain electrode may have a first side positioned on the source field plate side, the first side being in contact with the first protective film, the first side being perpendicular to the first direction, and the dielectric-breakdown suppression portion may be disposed to cross a region between, among points in the source field plate, a point closest to the drain electrode and the first side. In this case, it is easy to inhibit dielectric breakdown over a wide area.

[8] In [1] to [7], a dimension of the dielectric-breakdown inhibition portion in the first direction and a dimension of the dielectric-breakdown inhibition portion in the direction perpendicular to the first main surface may be 10 nm or more. Because the size of defect is generally less than 10 nm, in this case, dielectric breakdown can be effectively inhibited.

[9] A semiconductor device according to another aspect of the present disclosure includes a substrate, a nitride semiconductor layer formed on the substrate, a source electrode and a drain electrode formed in the nitride semiconductor layer, the source electrode and the drain electrode being arranged side by side in a first direction parallel to a first main surface of the substrate, a gate electrode formed on the nitride semiconductor layer, the gate electrode being positioned between the source electrode and the drain electrode, a Si nitride film formed on the nitride semiconductor layer, the Si nitride film covering the source electrode, the drain electrode, and the gate electrode, a source field plate formed on the Si nitride film, the source field plate being electrically connected to the source electrode, the source field plate being positioned between the gate electrode and the drain electrode in a plan view in a direction perpendicular to the first main surface and a space formed in the first protective film, the space including a part positioned between an end of the source field plate on the drain electrode side and an end of the drain electrode on the source field plate side in a sectional view in a second direction parallel to the first main surface and perpendicular to the first direction. A dimension of the space in the first direction is 50 nm or more, and a dimension of the space in the direction perpendicular to the first main surface is 100 nm or more.

[10] A method of manufacturing a semiconductor device according to another aspect of the present disclosure includes forming a nitride semiconductor layer on a substrate, forming, in the nitride semiconductor layer, a source electrode and a drain electrode arranged side by side in a first direction parallel to a first main surface of the substrate, forming, on the nitride semiconductor layer, a gate electrode positioned between the source electrode and the drain electrode, forming, on the nitride semiconductor layer, a first protective film covering the source electrode, the drain electrode, and the gate electrode, forming, on the first protective film, a source field plate electrically connected to the source electrode, and that is the source field plate being positioned between the gate electrode and the drain electrode in a plan view in a direction perpendicular to the first main surface and forming a dielectric-breakdown inhibition portion including a part positioned between an end of the source field plate on a the drain electrode side and an end of the drain electrode on the source field plate side in a sectional view in a second direction parallel to the first main surface and perpendicular to the first direction, and that is the dielectric-breakdown inhibition portion being configured to inhibit dielectric breakdown of the first protective film.

[11] In [10], the forming the dielectric-breakdown inhibition portion may include, in the forming the first protective film, forming a first insulating film covering the source electrode, the drain electrode, and the gate electrode, forming, at the first insulating film, a recess including a part positioned between the end of the source field plate on the side of the drain electrode and the end of the drain electrode on the side of the source field plate in the sectional view, and forming a second insulating film on the first insulating film such that at least a part of the recess is left as a space. In this case, it is easy to form the space as the dielectric-breakdown inhibition portion.

Details of Embodiments of the Present Disclosure Hereinafter, embodiments of the present disclosure will be described in detail, but the present disclosure is not limited thereto. In the specification and the drawings, components having substantially the same functional configuration are denoted by the same reference numerals, and redundant description thereof may be omitted.

### First Embodiment

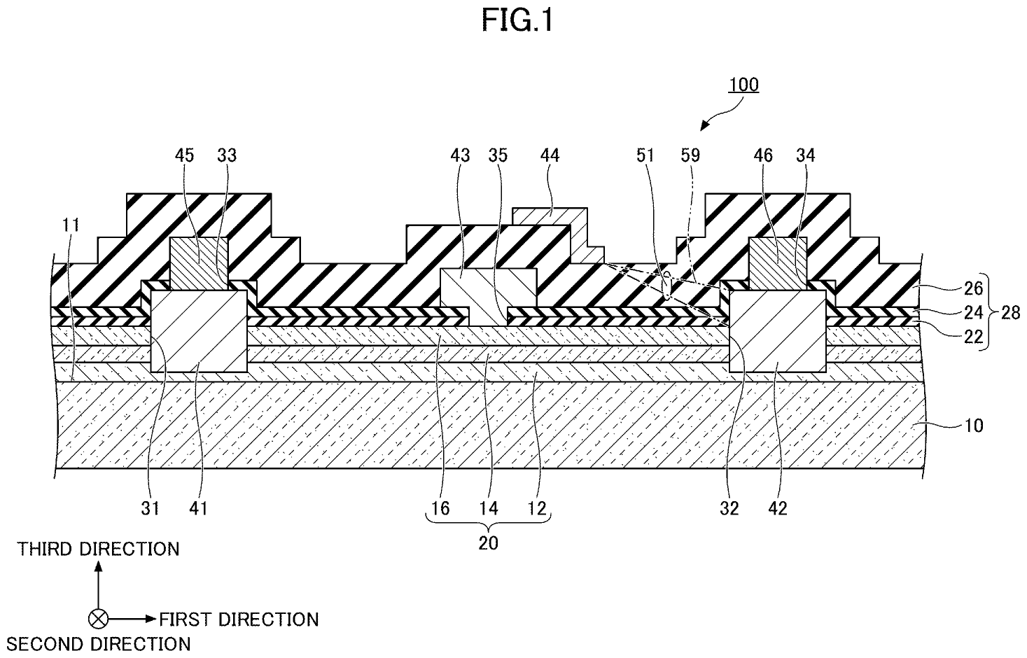

First, a first embodiment will be described. The first embodiment relates to a semiconductor device including a GaN-HEMT having a nitride semiconductor as a main constituent material. FIG. 1 is a cross-sectional view illustrating a semiconductor device according to a first embodiment. FIG. 1 illustrates a cross section perpendicular to the gate width direction.

As illustrated in FIG. 1, a semiconductor device 100 according to the first embodiment includes a substrate 10 having a first main surface 11 and a multi-layer structure 20 including a plurality of nitride semiconductor layers formed on first main surface 11 of substrate 10. Substrate 10 is, for example, a SiC substrate having a (0001) plane, and the stacking direction of multi-layer structure 20 is, for example, a [0001] direction. Multi-layer structure 20 includes an electron transit layer 12, an electron supply layer 14, and a cap layer 16 that are sequentially formed on substrate 10. Electron transit layer 12 is, for example, an undoped GaN layer having a thickness of about 1000 nm. Electron supply layer 14 is, for example, an n-type AlGaN layer having a thickness of about 20 nm. Cap layer 16 is, for example, a GaN layer having a thickness of about 5 nm. Multi-layer structure 20 is an example of the nitride semiconductor layer.

An insulating film 22 is formed on multi-layer structure 20. Insulating film 22 is, for example, a Si nitride film. An opening 31 for a source electrode and an opening 32 for a drain electrode are formed in insulating film 22 and multi-layer structure 20. A source electrode 41 in ohmic contact with multi-layer structure 20 is formed in opening 31, and a drain electrode 42 in ohmic contact with multi-layer structure 20 is formed in opening 32. Source electrode 41 and drain electrode 42 are aligned in a direction parallel to first main surface 11 of substrate 10. In the present disclosure, a direction in which source electrode 41 and drain electrode 42 are arranged is referred to as a first direction, a direction parallel to first main surface 11 and perpendicular to the first direction is referred to as a second direction, and a direction perpendicular to first main surface 11 is referred to as a third direction. The plan view refers to a plan view from the third direction, and the cross-sectional view refers to a cross-sectional view from the second direction. Each of source electrode 41 and drain electrode 42 includes, for example, a Ti film and an Al film formed on the Ti film. An insulating film 24 is formed on insulating film 22, source electrode 41, and drain electrode 42. Insulating film 24 is, for example, a Si nitride film.

An opening 35 for a gate electrode 43 is formed in insulating films 22 and 24 between source electrode 41 and drain electrode 42. Gate electrode 43 in Schottky contact with multi-layer structure 20 is formed in opening 35. A part of gate electrode 43 may be on insulating film 24. Gate electrode 43 includes, for example, a Ni film and an Au film formed on the Ni film.

An opening 33 for a source wiring 45 and an opening 34 for a drain wiring 46 are formed in insulating film 24. Source wiring 45 connected to source electrode 41 is formed in opening 33, and drain wiring 46 connected to drain electrode 42 is formed in opening 34. Source wiring 45 and drain wiring 46 include, for example, an Au film. An insulating film 26 is formed on insulating film 24, source wiring 45, gate electrode 43, and drain wiring 46. Insulating film 26 is, for example, a Si nitride film. Insulating films 22, 24, and 26 are included in a first protective film 28.

A source field plate 44 is formed on insulating film 26. Source field plate 44 is electrically connected to source electrode 41 through a path not illustrated in FIG. 1. Source field plate 44 is located between gate electrode 43 and drain electrode 42 in the plan view. Source field plate 44 includes, for example, a Ti film and a Ni film formed on the Ti film. Source field plate 44 may be connected to source electrode 41 through a path illustrated in FIG. 1, that is, so as to cover gate electrode 43 from above insulating film 26.

A space 51 is formed in insulating film 26. Space 51 is located between an end of source field plate 44 on drain electrode 42 side and an end of drain electrode 42 on source field plate 44 side in the cross-sectional view. Space 51 preferably includes a part located on the shortest line segment 59 among line segments connecting a point in source field plate 44 and a point in drain electrode 42 in the cross-sectional view. For example, the dimension of space 51 in the first direction is about 50 nm, and the dimension of space 51 in the third direction is about 100 nm. Space 51 is an example of a dielectric-breakdown inhibition portion.

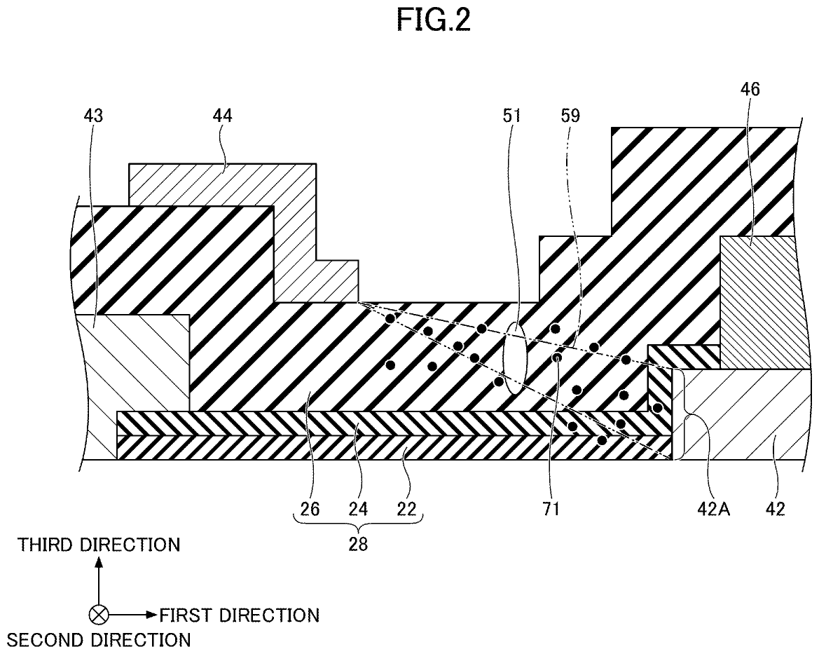

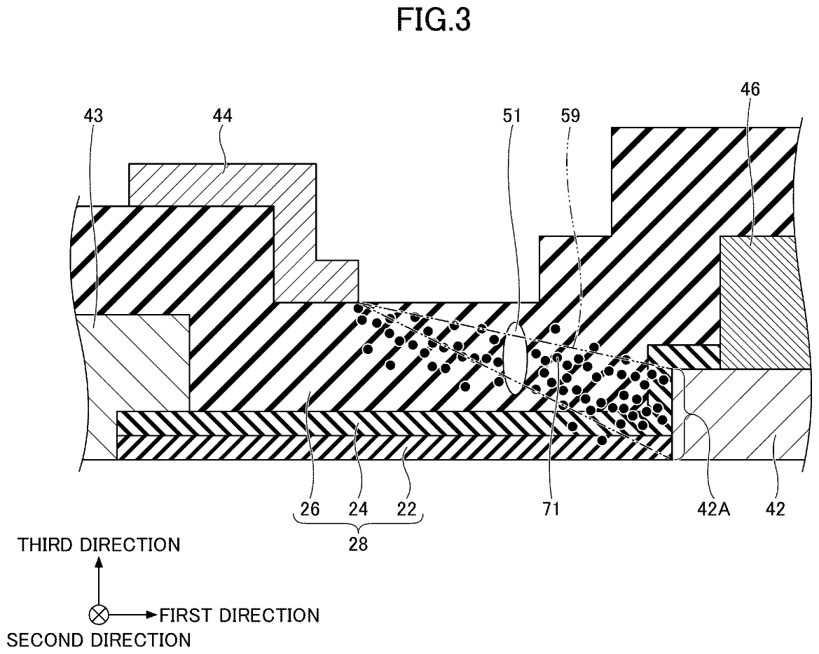

Here, effects of semiconductor device 100 according to the first embodiment will be described. FIGS. 2 and 3 are cross-sectional views illustrating the effects of semiconductor device 100 according to the first embodiment.

When semiconductor device 100 operates, an electric field is generated between source field plate 44 and drain electrode 42, and a plurality of defects 71 occur in first protective film 28 over time, as illustrated in FIG. 2. The size of each defect 71 is generally less than 10 nm.

As illustrated in FIG. 3, as the operation time is longer, defects 71 are connected to each other. When a plurality of defects 71 are connected between source field plate 44 and drain electrode 42, the connected defects 71 may be a leak path. On the other hand, in the first embodiment, space 51 is formed in first protective film 28. Even if the plurality of defects 71 are connected on source field plate 44 side with respect to space 51 and if the plurality of defects 71 are connected on drain electrode 42 side with respect to space 51, defect that becomes a leak path is not generated in space 51. Therefore, generation of a leak path connecting source field plate 44 and drain electrode 42 is inhibited.

Therefore, even if the distance between gate electrode 43 and drain electrode 42 is reduced and the distance between source field plate 44 and drain electrode 42 is reduced, dielectric breakdown of first protective film 28 can be inhibited. By reducing the distance between gate electrode 43 and drain electrode 42, the resistance of the channel between gate electrode 43 and drain electrode 42 can be reduced. In addition, by reducing the distance between gate electrode 43 and drain electrode 42, semiconductor device 100 can be miniaturized; the number of semiconductor devices 100 that can be manufactured from one semiconductor wafer can be increased; and the material cost of semiconductor device 100 can be reduced.

The distance between gate electrode 43 and drain electrode 42 in the plan view is preferably 2.0 μm or less, more preferably 1.5 μm or less, and still more preferably 1.0 μm or less. As described above, even if the distance between gate electrode 43 and drain electrode 42 is small, dielectric breakdown of first protective film 28 is less likely to occur. The smaller the distance, the lower the channel resistance and the lower the material cost.

Further, the distance between source field plate 44 and drain electrode 42 in the plan view is preferably 1.0 μm or less, more preferably 0.7 μm or less, and still more preferably 0.5 μm or less. As described above, even if the distance between source field plate 44 and drain electrode 42 is short, dielectric breakdown of first protective film 28 is less likely to occur, and as this distance is shorter, it is easier to reduce the distance between gate electrode 43 and drain electrode 42.

In addition, in a case where space 51 is not formed, defect 71 is likely to be connected to line segment 59 having the shortest distance and the vicinity thereof. However, in the first embodiment, because space 51 includes a part on line segment 59, it is easy to inhibit connection of defects 71 between source field plate 44 and drain electrode 42.

In the cross-sectional view, space 51 is preferably positioned so as to cross a region between a first side 42A of drain electrode 42 and a point closest to drain electrode 42 among points in source field plate 44. First side 42A is located on source field plate 44 side, is in contact with first protective film 28, and is a side perpendicular to the first direction. By positioning space 51 in this manner, it is possible to inhibit the connection of defects 71 between source field plate 44 and drain electrode 42 over a wide area. Note that first side 42A may not be completely perpendicular to the first direction and may be, for example, a side that is inevitably inclined during etching.

It is preferable that the dimension of space 51 in the first direction and the dimension thereof in the third direction are 10 nm or more. As described above, the size of each defect 71 that occurs over time is generally less than 10 nm. Therefore, when the dimension in the first direction and the dimension in the third direction are 10 nm or more, it is easy to inhibit the connection of defects 71. The dimension in the first direction is preferably 30 nm or more, and more preferably 50 nm or more. The dimension in the third direction is preferably 50 nm or more, and more preferably 100 nm or more.

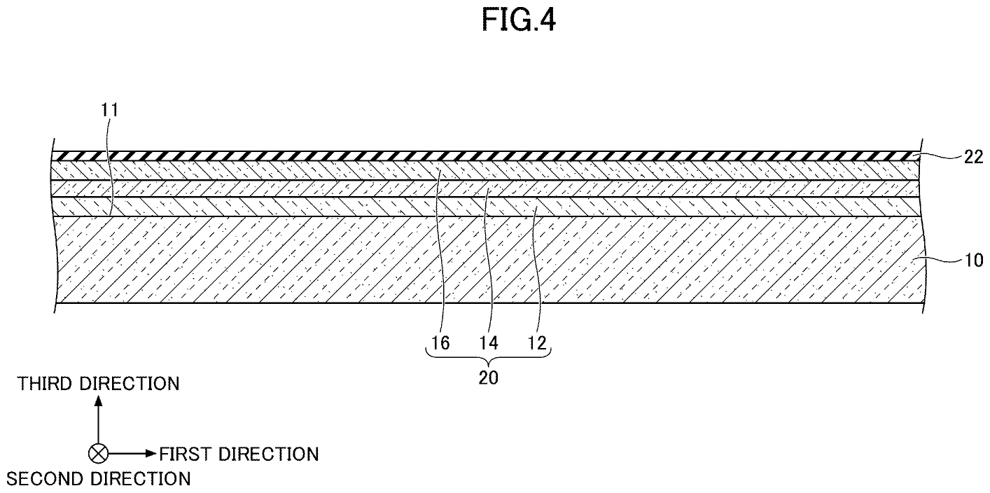

Next, a method of manufacturing semiconductor device 100 according to the first embodiment will be described. FIGS. 4 to 10 are cross-sectional views illustrating a method for manufacturing semiconductor device 100 according to the first embodiment.

First, as illustrated in FIG. 4, multi-layer structure 20 including a plurality of nitride semiconductor layers is grown on substrate 10 using a metal organic chemical vapor deposition (MOCVD) method. Next, insulating film 22 in contact with the upper surface of multi-layer structure 20 is formed using a low pressure (LP) CVD method. Insulating film 22 is, for example, a silicon nitride film having a thickness of 40 nm. Before forming electron transit layer 12, a nucleation layer may be formed on substrate 10, and electron transit layer 12 may be formed on the nucleation layer. The nucleation layer is, for example, an AlN layer having a thickness of several tens of nm.

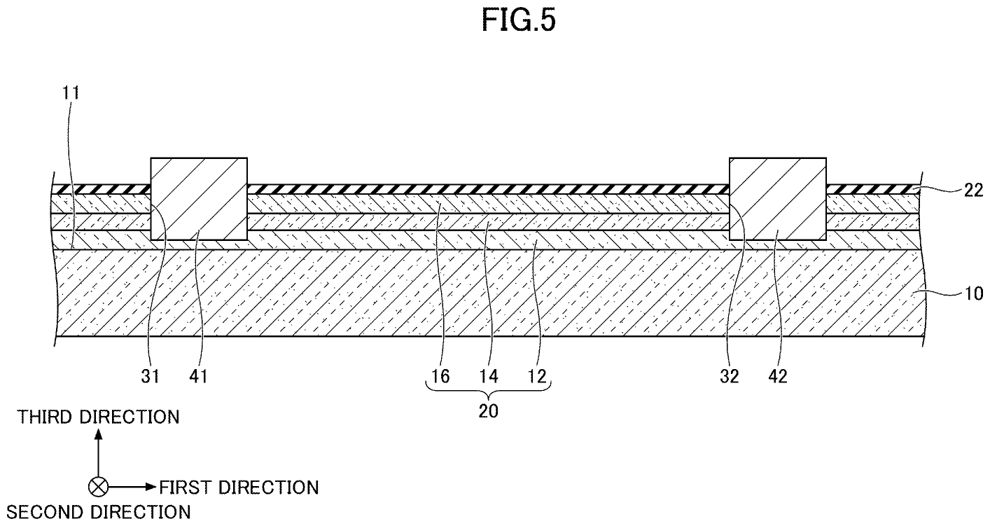

Next, as illustrated in FIG. 5, opening 31 for a source electrode and opening 32 for a drain electrode are formed on insulating film 22 and multi-layer structure 20; source electrode 41 is formed in opening 31; and drain electrode 42 is formed in opening 32.

In the formation of openings 31 and 32, for example, reactive ion etching (RIE) of insulating film 22 and multi-layer structure 20 is performed using a mask provided with openings. In addition, in the formation of source electrode 41 and drain electrode 42, for example, forming of a metal layer by a vapor deposition method using a mask used for forming openings 31 and 32 as a growth mask, a removal (lift-off) of the mask, and alloying of the metal layer by heat treatment are performed.

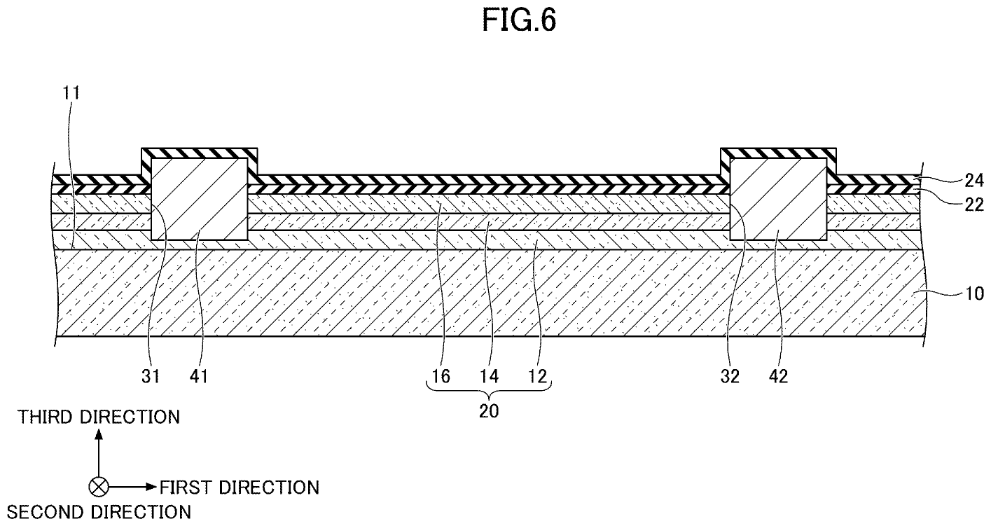

Next, as illustrated in FIG. 6, insulating film 24 is formed on insulating film 22, source electrode 41, and drain electrode 42 using a plasma enhanced (PE) CVD method. Insulating film 24 is, for example, a silicon nitride film having a thickness of 20 nm.

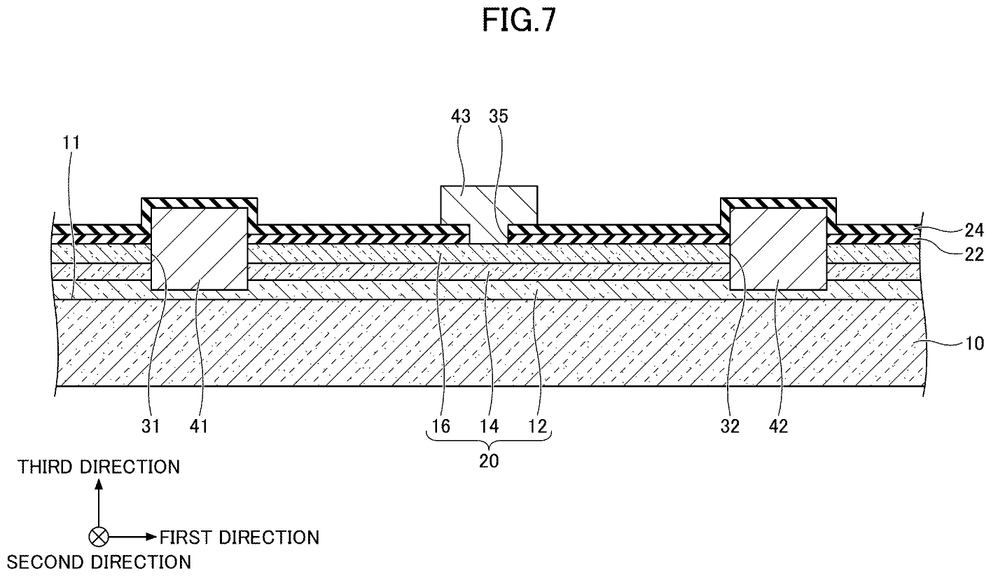

Next, as illustrated in FIG. 7, opening 35 for gate electrode 43 is formed in insulating films 24 and 22 between source electrode 41 and drain electrode 42, and a gate electrode 43 is formed in opening 35. Apart of gate electrode 43 may be formed on insulating film 24.

In the formation of opening 35, for example, RIE of insulating film 24 and insulating film 22 is performed using a mask provided with opening. In the formation of gate electrode 43, for example, a metal layer is formed by a vapor deposition method using another mask having an opening as a growth mask, and the masks are removed (lifted off).

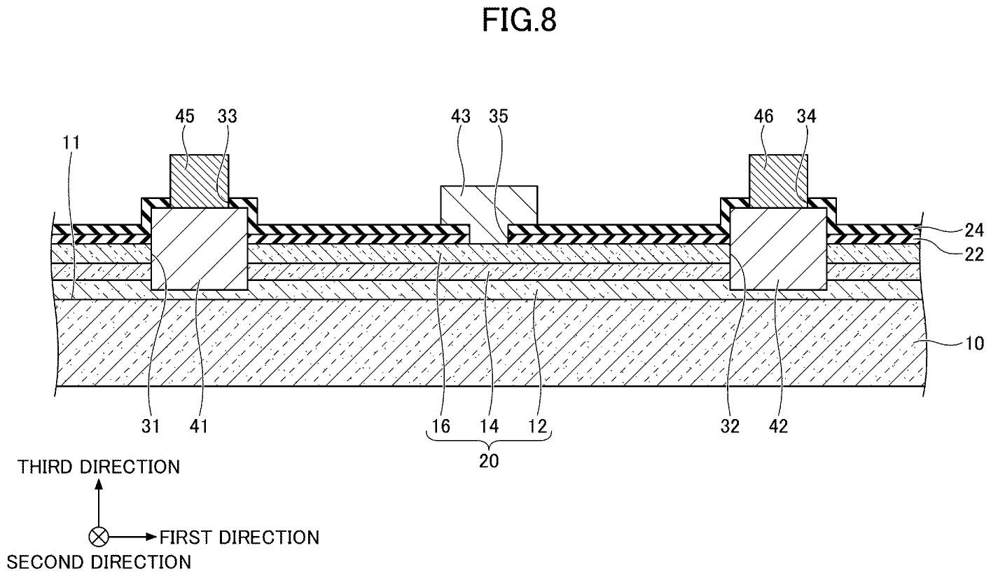

Next, as illustrated in FIG. 8, opening 33 for source wiring 45 and opening 34 for drain wiring 46 are formed in insulating film 24; source wiring 45 is formed in opening 33; and drain wiring 46 is formed in opening 34.

In the formation of openings 33 and 34, for example, RIE of insulating film 24 is performed using a mask having openings. Source wiring 45 and drain wiring 46 can be formed by, for example, a plating method.

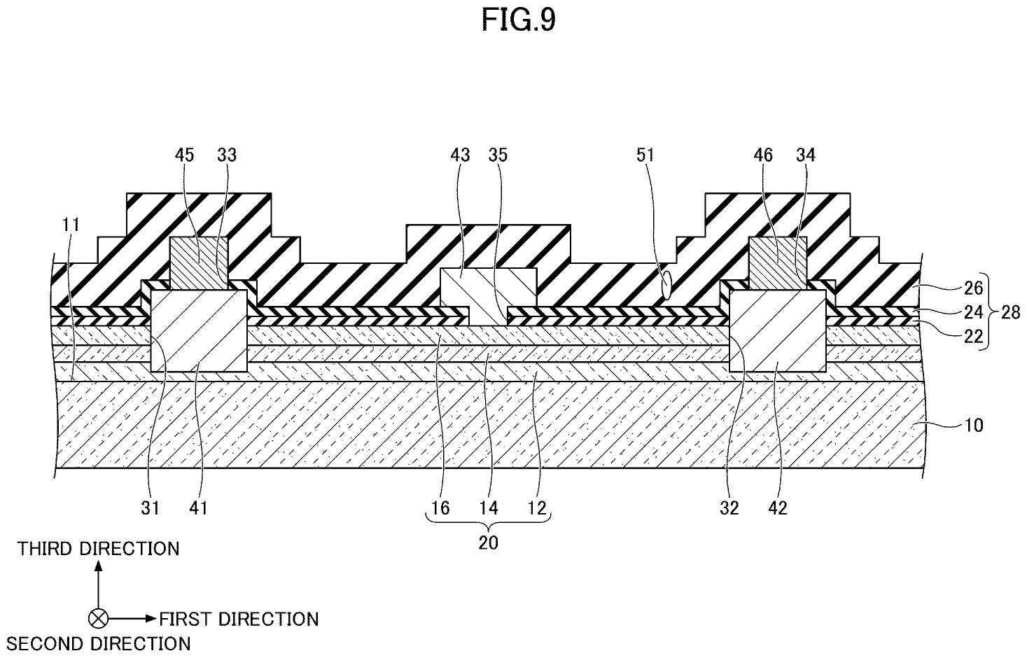

Next, as illustrated in FIG. 9, insulating film 26 and space 51 are formed on insulating film 24, source wiring 45, gate electrode 43, and drain wiring 46. Insulating film 26 is made of, for example, a silicon nitride film having a thickness of 400 nm. Insulating films 22, 24, and 26 are included in first protective film 28. A method of forming insulating film 26 and space 51 will be described later.

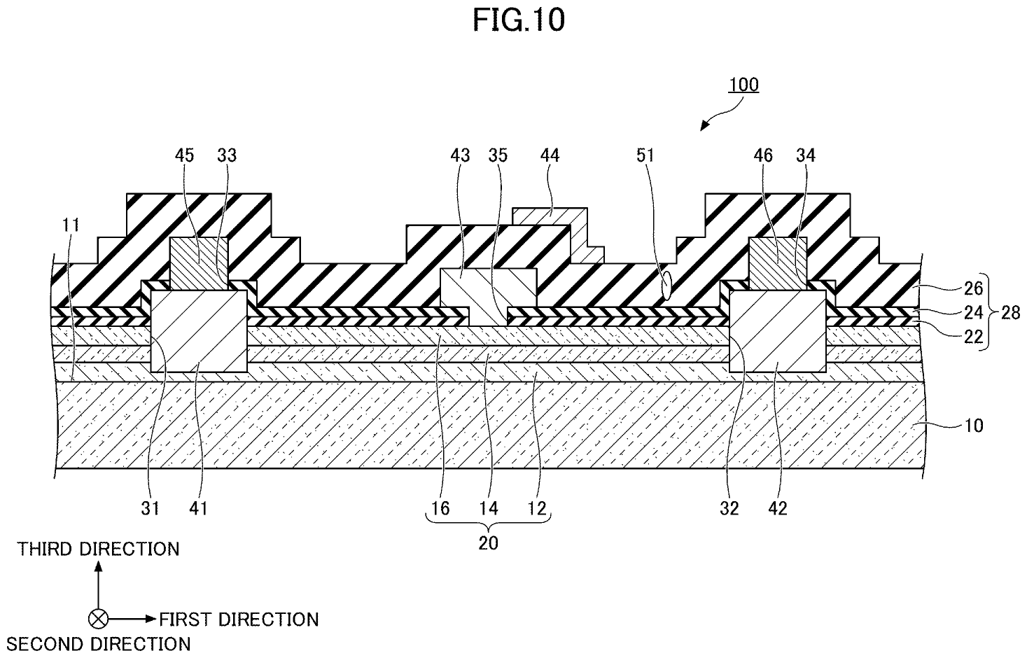

Next, as illustrated in FIG. 10, source field plate 44 is formed on insulating film 26. Source field plate 44 is electrically connected to source electrode 41 through a path that is not illustrated in FIG. 1. Source field plate 44 is located between gate electrode 43 and drain electrode 42 in the plan view. In the formation of source field plate 44, for example, a metal layer is formed by a vapor deposition method using a mask having an opening as a growth mask, and the mask is removed (lifted off).

Thereafter, a wiring or the like is formed as necessary. In this manner, semiconductor device 100 including the GaN-HEMT can be manufactured.

A method of forming insulating film 26 and space 51 will be described. FIGS. 11 to 14 are cross-sectional views illustrating a method of forming insulating film 26 and space 51. FIGS. 11 to 14 illustrate a region between source field plate 44 and drain electrode 42 in the plan view.

First, as illustrated in FIG. 11, a first insulating film 26A is formed on insulating film 24, source wiring 45, gate electrode 43, and drain wiring 46. First insulating film 26A is a silicon nitride film. First insulating film 26A is thinner than insulating film 26. The thickness of first insulating film 26A is, for example, 300 nm. First insulating film 26A can be formed by, for example, a plasma CVD method.

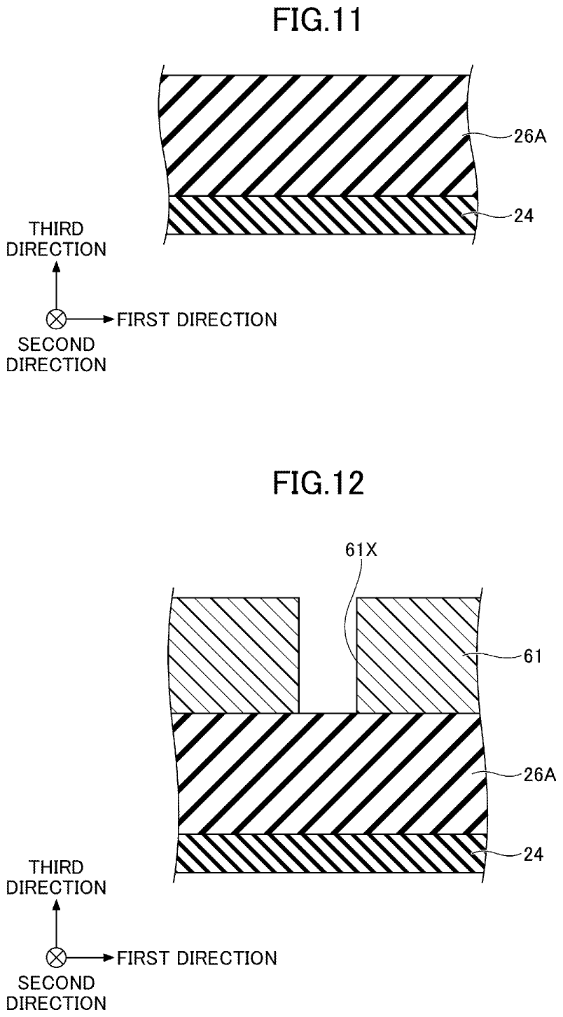

Next, as illustrated in FIG. 12, an i-line resist 61 is applied on first insulating film 26A, and an opening 61X is formed in i-line resist 61 by photolithography. First insulating film 26A is exposed through opening 61X. For example, i-line resist 61 has a thickness of 650 nm, and the dimension (opening width) of opening 61X is 300 nm.

Next, as illustrated in FIG. 13, RIE of first insulating film 26A is performed using i-line resist 61 as a mask and using a mixture gas of CHF₃ and O₂ as an etching gas. When a mixture gas of CHF₃ and O₂ is used, a reaction product 62 generated by etching first insulating film 26A is likely to adhere to the side wall surface of opening 61X. Therefore, a recess 26X that narrows toward the bottom is formed in first insulating film 26A. For example, in the cross-sectional view of recess 26X, the ratio of the depth D of recess 26X to the shortest length W between reaction products 62 facing each other is 2.0 or more.

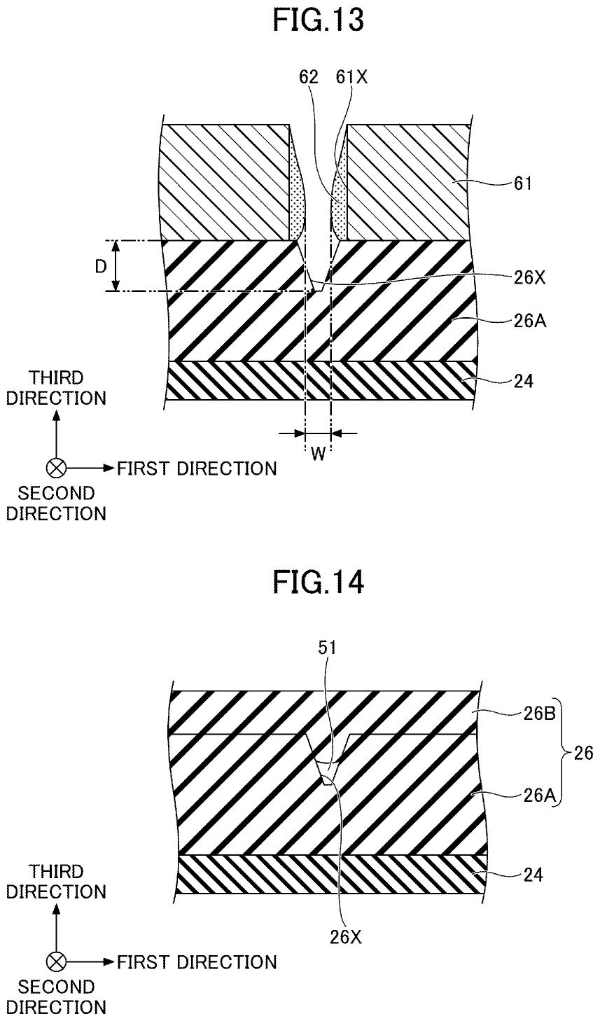

Next, as illustrated in FIG. 14, i-line resist 61 is removed. Next, a second insulating film 26B is formed on first insulating film 26A. Second insulating film 26B is a silicon nitride film. Second insulating film 26B is thinner than insulating film 26. The thickness of second insulating film 26B is, for example, 100 nm. Second insulating film 26B can be formed by, for example, a low pressure CVD method. At this time, second insulating film 26B cannot fill recess 26X, and space 51 is formed.

In this manner, insulating film 26 composed of first insulating film 26A and second insulating film 26B and space 51 can be formed.

According to this method, it is possible to stably manufacture semiconductor device 100 including space 51 acting as the dielectric-breakdown inhibition portion.

### Second Embodiment

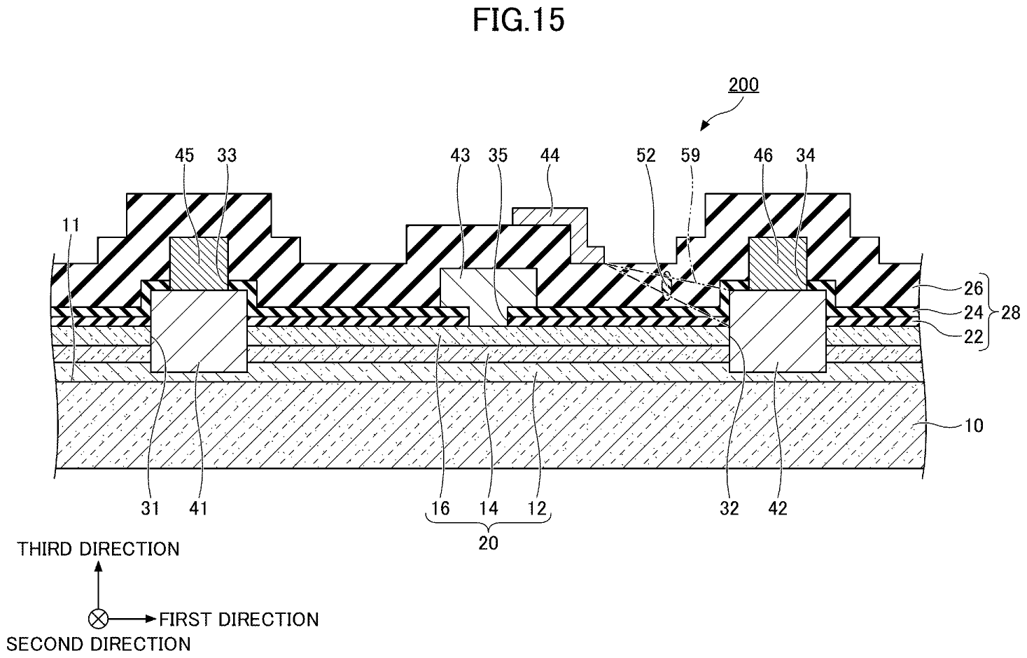

Next, a second embodiment will be described. The second embodiment differs from the first embodiment in the configuration of the dielectric-breakdown inhibition portion. FIG. 15 is a cross-sectional view illustrating a semiconductor device according to the second embodiment.

In a semiconductor device 200 according to the second embodiment, as illustrated in FIG. 15, a second protective film 52 is formed in place of space 51 in insulating film 26. That is, second protective film 52 is embedded in first protective film 28. Second protective film 52 is made of a material having a film density higher than that of first protective film 28. For example, first protective film 28 is a silicon nitride film and has a film density of about 3.2 g/cm³, whereas second protective film 52 is an aluminum oxide film and has a film density of about 3.9 g/cm³. Second protective film 52 is an example of the dielectric-breakdown inhibition portion. The film density is a mass per unit volume of the film and can be measured by, for example, an X-ray reflectivity.

Other configurations are the same as those of the first embodiment.

Although not illustrated in FIG. 15, second protective film 52 may be formed not only at the position of space 51 in the first embodiment but also over the entire first protective film 28. This can be understood from the description of the method of forming the insulating film 26 described later.

Also in semiconductor device 200 according to the second embodiment, as the operation time is longer, a plurality of defects 71 occur in first protective film 28 between source field plate 44 and drain electrode 42. However, because the film density of second protective film 52 is higher than that of first protective film 28, defects are less likely to occur in second protective film 52. Therefore, even if a plurality of defects 71 are connected on source field plate 44 side with respect to second protective film 52 and if a plurality of defects 71 are connected on drain electrode 42 side with respect to second protective film 52, defect that serves as a leak path is less likely to occur in second protective film 52, and thus occurrence of a leak path connecting source field plate 44 and drain electrode 42 is inhibited.

Therefore, as in the first embodiment, by reducing the distance between gate electrode 43 and drain electrode 42, the resistance of the channel between gate electrode 43 and drain electrode 42 can be reduced, and the material cost of semiconductor device 100 can be reduced.

The film density of second protective film 52 should be higher than that of first protective film 28. The film density of second protective film 52 is preferably 3.4 g/cm³ or higher, more preferably 3.6 g/cm³ or higher, and still more preferably 3.8 g/cm³ or higher. When first protective film 28 is a Si nitride film and when second protective film 52 is an Al oxide film, it is easy to form the films using an existing manufacturing apparatus.

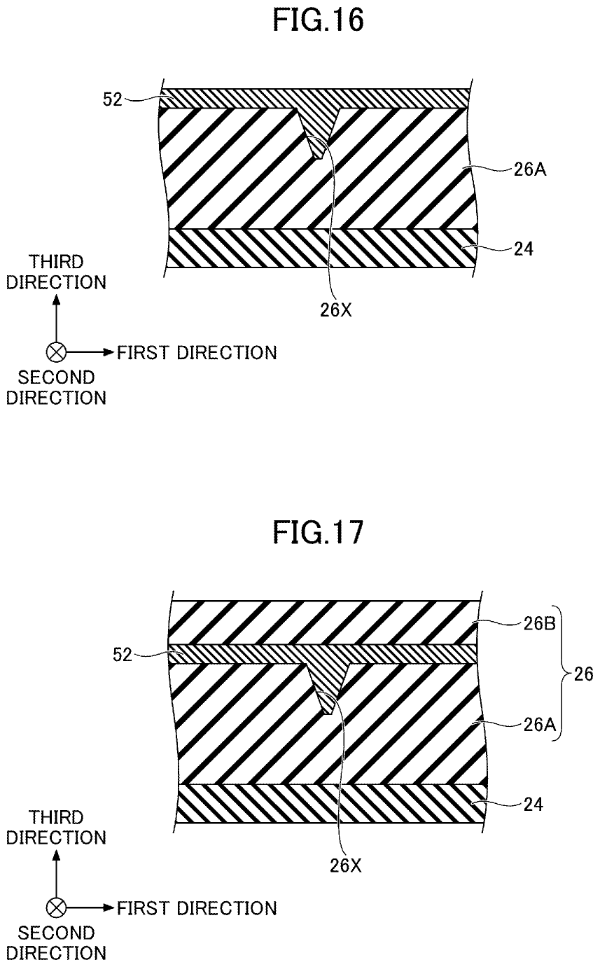

Next, a method of forming insulating film 26 and second protective film 52 will be described. FIGS. 16 and 17 are cross-sectional views illustrating a method of forming insulating film 26 and second protective film 52. FIGS. 16 and 17 illustrate a region between source field plate 44 and drain electrode 42 in the plan view.

First, as illustrated in FIG. 16, processing up to the formation of recess 26X is performed in the same manner as in the first embodiment. Next, second protective film 52 is formed on first insulating film 26A. Second protective film 52 is an Al oxide film. The thicknesses of second protective film 52 is, for example, 35 nm in the flat part. The thicknesses of second protective film 52 referred to herein are thicknesses of parts on first insulating film 26A outside recess 26X. Second protective film 52 can be formed by an atomic layer deposition (ALD) method. The step coverage of the Al oxide film formed by the ALD method is good, and recess 26X is filled with second protective film 52.

Next, second insulating film 26B is formed on second protective film 52. Second insulating film 26B is a silicon nitride film. Second insulating film 26B is thinner than insulating film 26. The thickness of second insulating film 26B is, for example, 100 nm. Second insulating film 26B can be formed by, for example, a low pressure CVD method.

In this manner, insulating film 26 including first insulating film 26A and second insulating film 26B and second protective film 52 can be formed. Before second insulating film 26B is formed, second protective film 52 may be removed except for the portion inside recess 26X.

### Third Embodiment

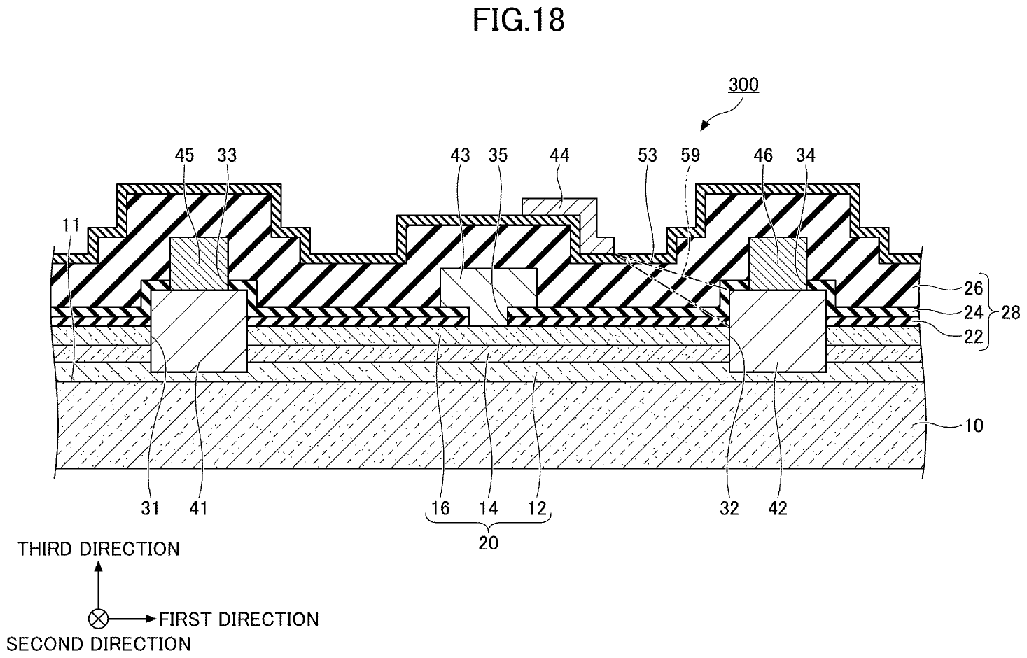

Next, a third embodiment will be described. The third embodiment differs from the first and second embodiments in the configuration of the dielectric-breakdown inhibition portion. FIG. 18 is a cross-sectional view illustrating a semiconductor device according to a third embodiment.

In a semiconductor device 300 according to the third embodiment, as illustrated in FIG. 18, neither space 51 nor second protective film 52 is formed in insulating film 26, and a third protective film 53 is formed on insulating film 26. Third protective film 53 is made of a material having a film density higher than that of first protective film 28. For example, first protective film 28 is a silicon nitride film, and the film density of first protective film 28 is about 3.2 g/cm³, whereas third protective film 53 is an aluminum oxide film, and the film density of third protective film 53 is about 3.9 g/cm³. Source field plate 44 is formed on third protective film 53. Third protective film 53 is an example of the dielectric-breakdown inhibition portion.

Other configurations are the same as those of the first embodiment.

Also in semiconductor device 300 according to the third embodiment, as the operation time is longer, a plurality of defects 71 occur in first protective film 28 between source field plate 44 and drain electrode 42. However, because the film density of third protective film 53 is higher than that of first protective film 28, defects are less likely to occur in third protective film 53. Therefore, even if a plurality of defects 71 are connected on drain electrode 42 side with respect to third protective film 53, defect that serves as a leak path is less likely to occur in third protective film 53, and thus occurrence of a leak path connecting source field plate 44 and drain electrode 42 is inhibited.

Therefore, as in the first embodiment, by reducing the distance between gate electrode 43 and drain electrode 42, the resistance of the channel between gate electrode 43 and drain electrode 42 can be reduced, and the material cost of semiconductor device 100 can be reduced.

The film density of third protective film 53 should be higher than that of first protective film 28. The film density of third protective film 53 is preferably 3.4 g/cm³ or higher, more preferably 3.6 g/cm³ or higher, and still more preferably 3.8 g/cm³ or higher.

Next, an experiment conducted by the present inventors will be described. In this experiment, a sample was prepared according to the first embodiment as Sample No. 1. A sample in which no space was formed in first protective film was also prepared as Sample No. 2. Sample No. 1 and Sample No. 2 had the same structure except with or without space. Note that the distance between a source field plate and a drain electrode in the plan view was 1 μm. In a conventional semiconductor device, the distance between a source field plate and a drain electrode in the plan view is at least about 3 μm, and this distance of 1 μm is an extremely short.

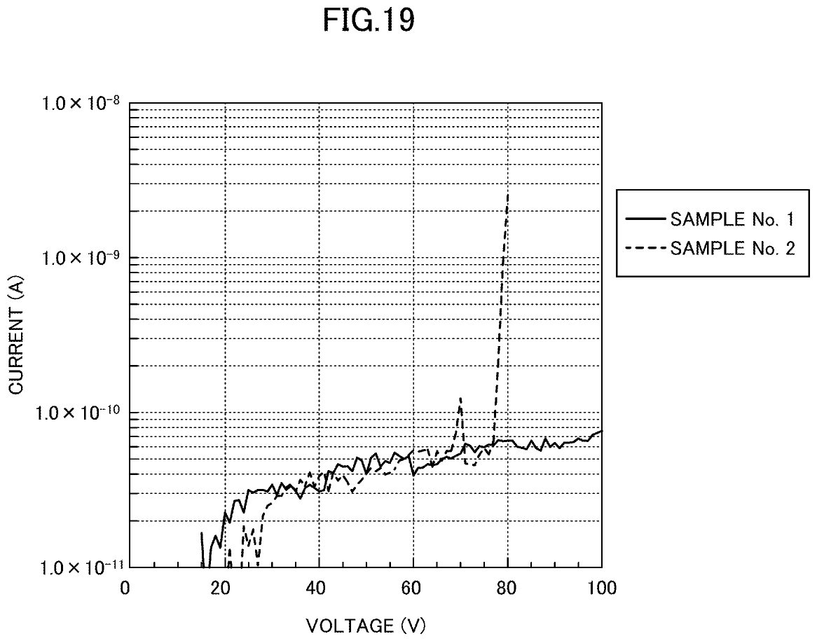

Then, the relationship (I-V characteristics) between the voltage applied between a source field plate and a drain electrode and the current flowing between a source field plate and a drain electrode was examined for Samples No. 1 and No. 2. The results are shown in FIG. 19. FIG. 19 is a diagram illustrating an I-V characteristic. In FIG. 19, the horizontal axis represents the voltage between a source field plate and a drain electrode, and the vertical axis represents the current flowing between a source field plate and a drain electrode.

As shown in FIG. 19, in Sample No. 2 in which no space was formed, when the voltage of 80V was applied, the current rapidly increased. On the other hand, in the sample No. 1 in which a space was formed, even when the voltage of the 100V was applied, the increase in current was slight. From this result, it is found that the breakdown voltage of the sample No. 2 is 80V or less, whereas the breakdown voltage of the sample No. 1 is 100V or more. That is, it can be seen that the sample No. 1 has a dielectric breakdown voltage higher than that of the sample No. 2 by 25% or more.

Although the embodiment has been described above in detail, the present invention is not limited to the specific embodiment, and various modifications and changes can be made within the scope described in the claims.

What is claimed is:

1. A semiconductor device comprising:
a substrate;
a nitride semiconductor layer formed on the substrate;
a source electrode and a drain electrode formed in the nitride semiconductor layer, the source electrode and the drain electrode being arranged side by side in a first direction parallel to a first main surface of the substrate;
a gate electrode formed on the nitride semiconductor layer, the gate electrode being positioned between the source electrode and the drain electrode;
a first protective film formed on the nitride semiconductor layer, and that the first protective film covering the source electrode, the drain electrode, and the gate electrode;
a source field plate formed on the first protective film, the source field plate being electrically connected to the source electrode, the source field plate being positioned between the gate electrode and the drain electrode in a plan view in a direction perpendicular to the first main surface; and
a dielectric-breakdown inhibition portion including a part positioned between an end of the source field plate on the drain electrode side and an end of the drain electrode on the source field plate side in a sectional view in a second direction parallel to the first main surface and perpendicular to the first direction, the dielectric-breakdown inhibition portion being configured to inhibit dielectric breakdown of the first protective film.

2. The semiconductor device according to claim 1, wherein the dielectric-breakdown inhibition portion includes a space formed in the first protective film.

3. The semiconductor device according to claim 1, wherein the dielectric-breakdown inhibition portion includes a second protective film that has a film density higher than a film density of the first protective film.

4. The semiconductor device according to claim 3, wherein the first protective film is a Si nitride film, and the second protective film is an Al oxide film.

5. The semiconductor device according to claim 3, wherein the second protective film is embedded in the first protective film.

6. The semiconductor device according to claim 1, wherein the dielectric-breakdown inhibition portion includes a part that is positioned on, among line segments that connect a point in the source field plate and a point in the drain electrode, a shortest line segment in the sectional view.

7. The semiconductor device according to claim 1,
wherein, in the sectional view,
the drain electrode has a first side positioned on the side of the source field plate, the first side being in contact with the first protective film, the first side being perpendicular to the first direction, and
the dielectric-breakdown inhibition portion is disposed to cross a region between, among points in the source field plate, a point closest to the drain electrode and the first side.

8. The semiconductor device according to claim 1, wherein a dimension of the dielectric-breakdown inhibition portion in the first direction and a dimension of the dielectric-breakdown inhibition portion in the direction perpendicular to the first main surface is 10 nm or more.

9. A semiconductor device comprising:
a substrate;
a nitride semiconductor layer formed on the substrate;
a source electrode and a drain electrode formed in the nitride semiconductor layer, the source electrode and the drain electrode being arranged side by side in a first direction parallel to a first main surface of the substrate;
a gate electrode formed on the nitride semiconductor layer, the gate electrode being positioned between the source electrode and the drain electrode;
a Si nitride film formed on the nitride semiconductor layer, the Si nitride film covering the source electrode, the drain electrode, and the gate electrode;
a source field plate formed on the Si nitride film, the source filed plate being electrically connected to the source electrode, the source filed plate being positioned between the gate electrode and the drain electrode in a plan view in a direction perpendicular to the first main surface; and
a space formed in the first protective film, the space including a part positioned between an end of the source field plate on the drain electrode side and an end of the drain electrode on the source field plate side in a sectional view in a second direction parallel to the first main surface and perpendicular to the first direction,
wherein a dimension of the space in the first direction is 50 nm or more, and a dimension of the space in the direction perpendicular to the first main surface is 100 nm or more.

10. A method of manufacturing a semiconductor device comprising:
forming a nitride semiconductor layer on a substrate;
forming, in the nitride semiconductor layer, a source electrode and a drain electrode, the source electrode and the drain electrode being arranged side by side in a first direction parallel to a first main surface of the substrate;
forming, on the nitride semiconductor layer, a gate electrode positioned between the source electrode and the drain electrode;
forming, on the nitride semiconductor layer, a first protective film covering the source electrode, the drain electrode, and the gate electrode;
forming, on the first protective film, a source field plate electrically connected to the source electrode, the source field plate being positioned between the gate electrode and the drain electrode in a plan view in a direction perpendicular to the first main surface; and
forming a dielectric-breakdown inhibition portion including a part positioned between an end of the source field plate on the drain electrode side and an end of the drain electrode on the source field plate side in a sectional view in a second direction parallel to the first main surface and perpendicular to the first direction, the dielectric-breakdown inhibition portion being configured to inhibit dielectric breakdown of the first protective film.

11. The method of manufacturing a semiconductor device according to claim 10,
wherein the forming the dielectric-breakdown inhibition portion includes,
in the step of forming the first protective film,
forming a first insulating film covering the source electrode, the drain electrode, and the gate electrode,
forming, at the first insulating film, a recess including a part positioned between the end of the source field plate on the side of the drain electrode and the end of the drain electrode on the side of the source field plate in the sectional view, and
forming a second insulating film on the first insulating film such that at least a part of the recess is left as a space.
